(19) United States
(12) Patent Application Publication
(10) Pub. No.: US 2006/0218772 A1
(43) Pub. Date: Oct. 5, 2006

(54) System and method for manufacturing a hard disk drive suspension flexure and for preventing damage due to electrical arcing

(76) Inventors: Ming Gao Yao, Dongguan City (CN); Masashi Shiraishi, Kowloon (CN); Yi Ru Xie, Dongguan City (CN)

Correspondence Address: KENYON & KENYON LLP, RIVERPARK TOWERS, SUITE 600, 333 W. SAN CARLOS ST., SAN JOSE, CA, 95110, US

(21) Appl. No.: 11/440,538

(22) Filed: May 24, 2006

Related U.S. Application Data
(62) Division of application No. 10/691,172, filed on Oct. 22, 2003.

(30) Foreign Application Priority Data
Mar. 17, 2003 (WO) PCT/CN03/00194

(51) Int. Cl. G11B 5/127; G11C 5/12

(52) U.S. Cl. 29/603.03; 29/737

(57) ABSTRACT

A system and method are disclosed for manufacturing a hard disk drive suspension flexure and for preventing damage due to electrical arcing between traces and between a trace and a grounding structure. In one embodiment, one or more portions of the suspension flexure is etched and laminated with an insulative coating.

### BACKGROUND INFORMATION

The present invention relates to hard disk drives. More specifically, the invention relates to a system and method for manufacturing a hard disk drive suspension flexure and for preventing electrical spark damage.

In the art today, different methods are used to improve the recording density of hard disk drives. FIG. 1 provides an illustration of a typical disk drive with a typical drive arm configured to read from and write to a magnetic hard disk. Typically, voice-coil motors (VCM) 106 are used for controlling a hard drive's arm 102 motion across a magnetic hard disk 104. Because of the inherent tolerance (dynamic play) that exists in the placement of a recording head 108 by a VCM 106 alone, micro-actuators 110 are now being utilized to ‘fine tune’ head 108 placement. A VCM 106 is utilized for course adjustment and the micro-actuator 110 then corrects the placement on a much smaller scale to compensate for the VCM's 106 (with the arm 102) tolerance. This enables a smaller recordable track width, increasing the ‘tracks per inch’ (TPI) value of the hard disk drive (increasing the density).

FIG. 2 provides an illustration of a micro-actuator as used in the art. As described in Japanese patents, JP 2002-133803 and JP 2002-074871, a slider 202 (containing a read/write magnetic head; not shown) is utilized for maintaining a prescribed flying height above the disk surface 104 (See FIG. 1). U-shaped micro-actuators may have two ceramic beams 208 with two pieces PZT on each side of the beams (not show), which are bonded at two points 204 on the slider 202 enabling slider 202 motion independent of the drive arm 102 (See FIG. 1) The micro-actuator 206 is commonly coupled to a suspension 212, by electrical connector balls 207 (such as gold ball bonding (GBB) or solder bump bonding (SBB)) on each side of the micro-actuator frame 210. Similarly, there are commonly GBB or SBB electrical connectors 205 to couple the trailing edge of magnetic head(slider) 202 to the suspension 212. Under piezoelectric expansion and contraction, the U-shape micro-actuator 210 will deform, causing the magnetic head to move over the disk for fine adjustment.

FIG. 3 illustrates another micro-actuator design existing in the art. As shown in FIG. 3b, between the slider 302 and a suspension tongue 306, is an I-beam micro-actuator 303. The micro-actuator 303 may have two PZT beams 311 and 312. One end support 300 is coupled to the suspension tongue 306, and the other end support 305 is coupled to the magnetic head 302. Under PZT beam 311,312 expansion and contraction, the magnetic head moves back and forth to fine adjust the location of the head 302 on the magnetic disk (not shown). As shown in FIG. 3c, in the alternative, a micro-electro-mechanical system (MEMS) or other micro-actuator system (such as electromagnetic, electrostatic, capacitive, fluidic, thermal, etc.) may be used for fine positioning.

FIG. 4 illustrates a load beam configuration PZT micro-actuator typical in the art and disclosed in US patent application 20020145831. Two PZT components 411 and 412 are coupled to the suspension load beam 402. Under expansion and contraction, the head suspension 402 (with magnetic head 422) moves for fine adjustment.

FIG. 5 illustrates a typical suspension flexure design used for hard disk drives. As shown in FIG. 5a, there are two traces 501 for micro-actuator control, called channels A and B. As shown in FIG. 5e, 10 to 60V sinusoidal waveforms with opposing phases are used to excite the micro-actuator. The stainless steel of the suspension body 504 is used as the ground. The other four traces 502,503 are used for magnetic head read and write functions. As shown in FIG. 5c, a cross-section, A-A, of the flexure illustrates the polyimide layer 505, mounted to the stainless steel base layer 504. Typically, six traces 501,502,503 of a material such as copper are located on the polyimide layer 505. Because of variations in the fabrication process, the polyimide layer 505 may be thinner than desired. When this happens, an electrical arc (spark) 506 may occur during periods of high voltage at a micro-actuator trace 501 (with respect to ground 504). As shown in FIG. 5c, a spark 506 may occur between a micro-actuator trace 501 and ground 504.

In addition to inconsistent layer thickness, the spark problem can also be caused by environmental conditions, such as high humidity. As shown in FIG. 5d, a spark 506 can occur between two micro-actuator traces 501 (sinusoidal voltage with opposing phase) due to high humidity, etc. Also, particle contamination can cause the spark problem. A contaminant (not shown) existing between two micro-actuator traces 501 can provide a stepping stone for a spark 506, aiding its jump from one micro-actuator trace to another 501. Because high displacement is necessary for the micro-actuator, large trace voltages are necessary, increasing the likelihood of a spark problem.

It is therefore desirable to have a system and method for manufacturing a hard disk drive suspension flexure that prevents electrical spark damage, as well as having additional benefits.

### BRIEF DESCRIPTION OF THE DRAWINGS

FIG. 1 provides an illustration of a typical disk drive with a typical drive arm configured to read from and write to a magnetic hard disk.

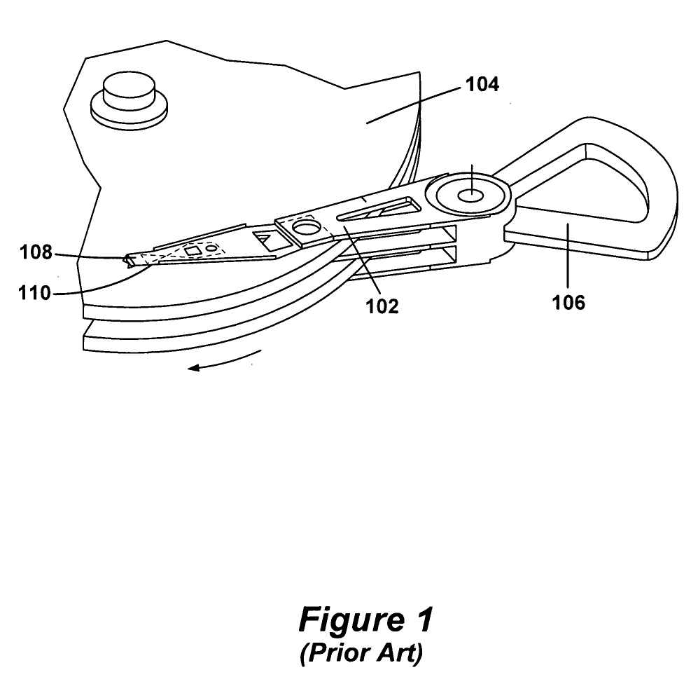

FIG. 2 provides an illustration of a micro-actuator as used in the art.

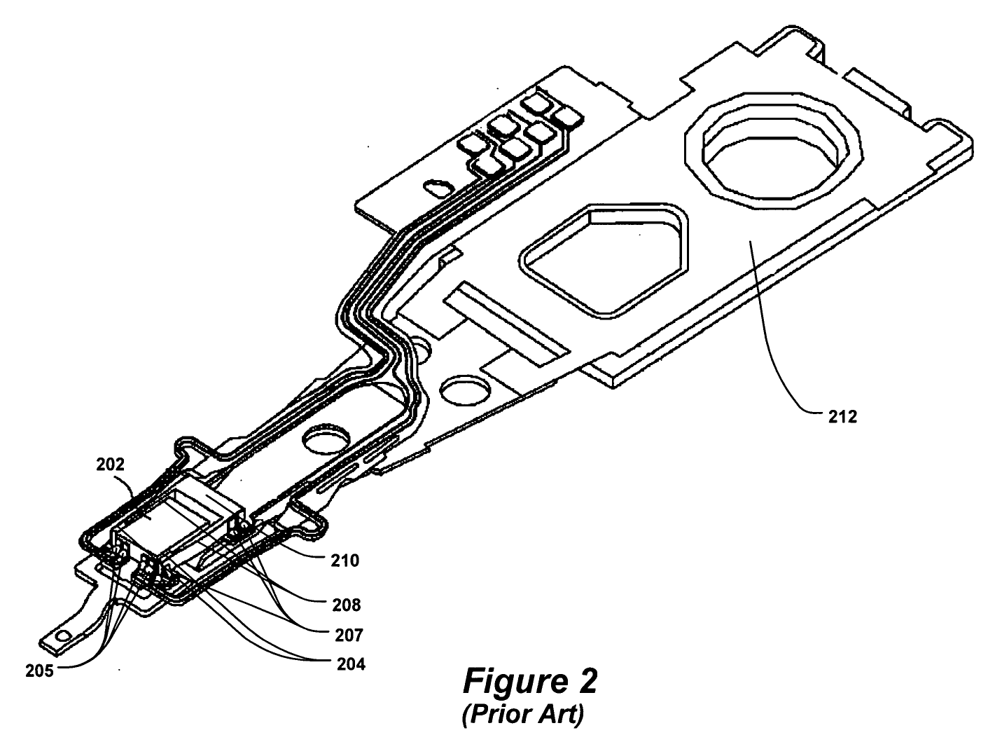

FIG. 3 illustrates another micro-actuator design existing in the art.

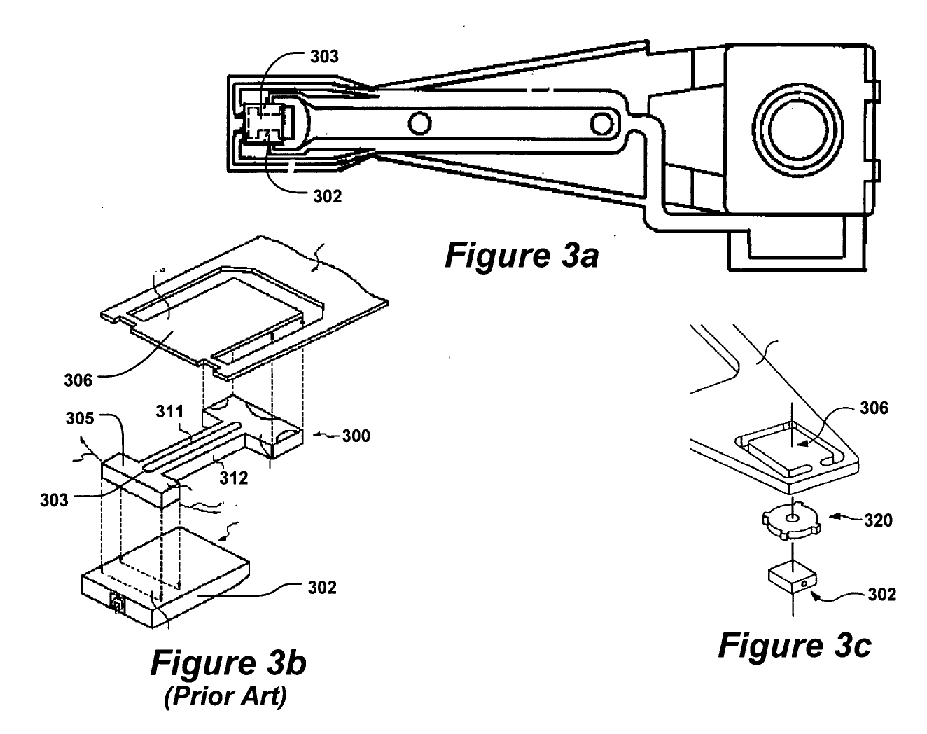

FIG. 4 illustrates a load beam configuration PZT micro-actuator typical in the art and disclosed in US patent application 20020145831.

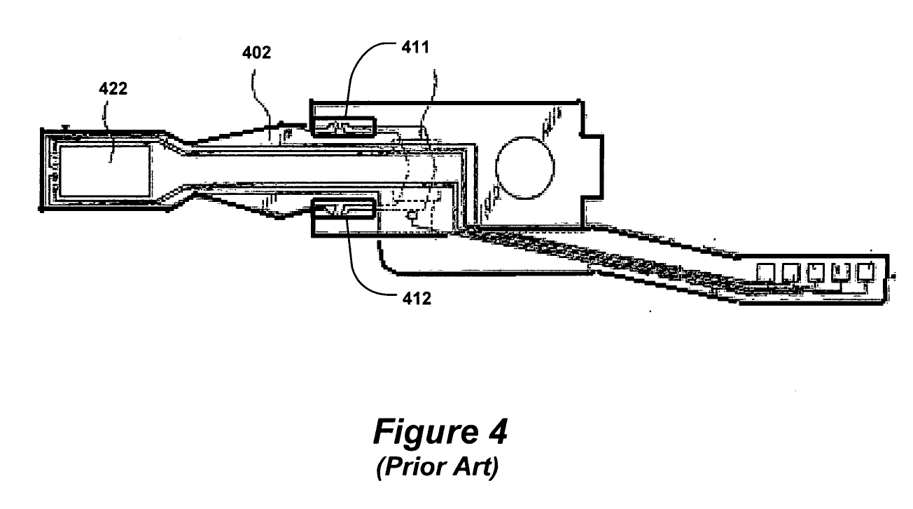

FIG. 5 illustrates a typical suspension flexure design used for hard disk drives.

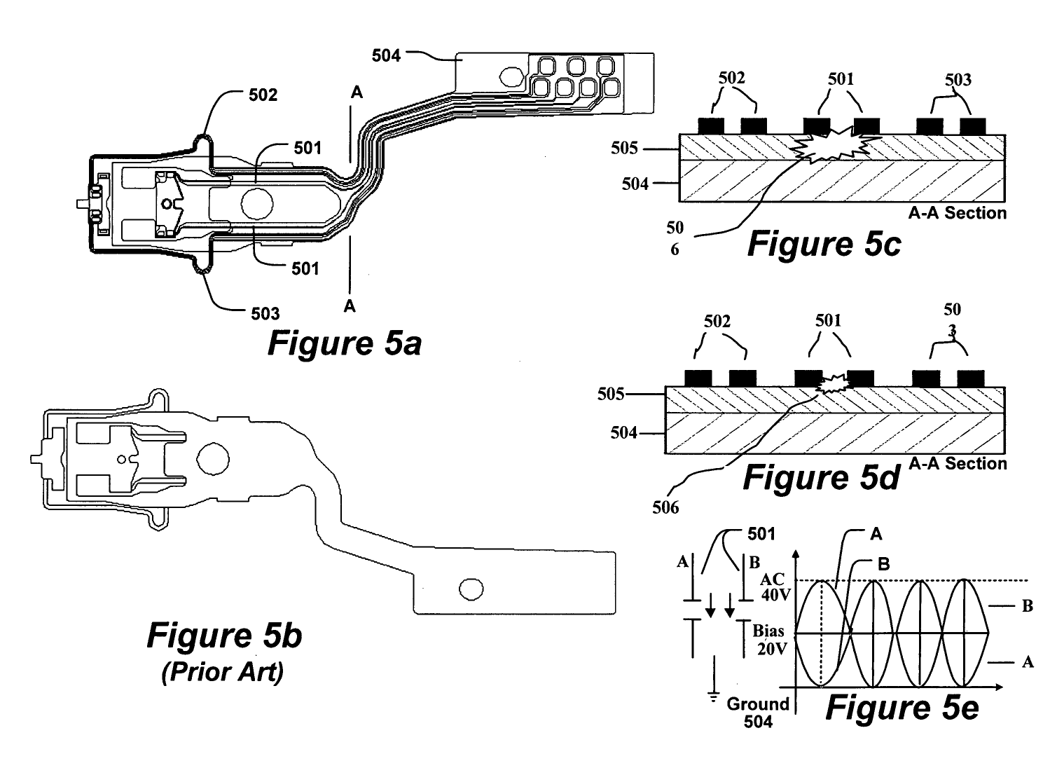

FIG. 6 illustrates a hard disk drive suspension flexure according to an embodiment of the present invention.

FIG. 7 illustrates the process of etching and laminating a suspension flexure according to an embodiment of the present invention.

### DETAILED DESCRIPTION

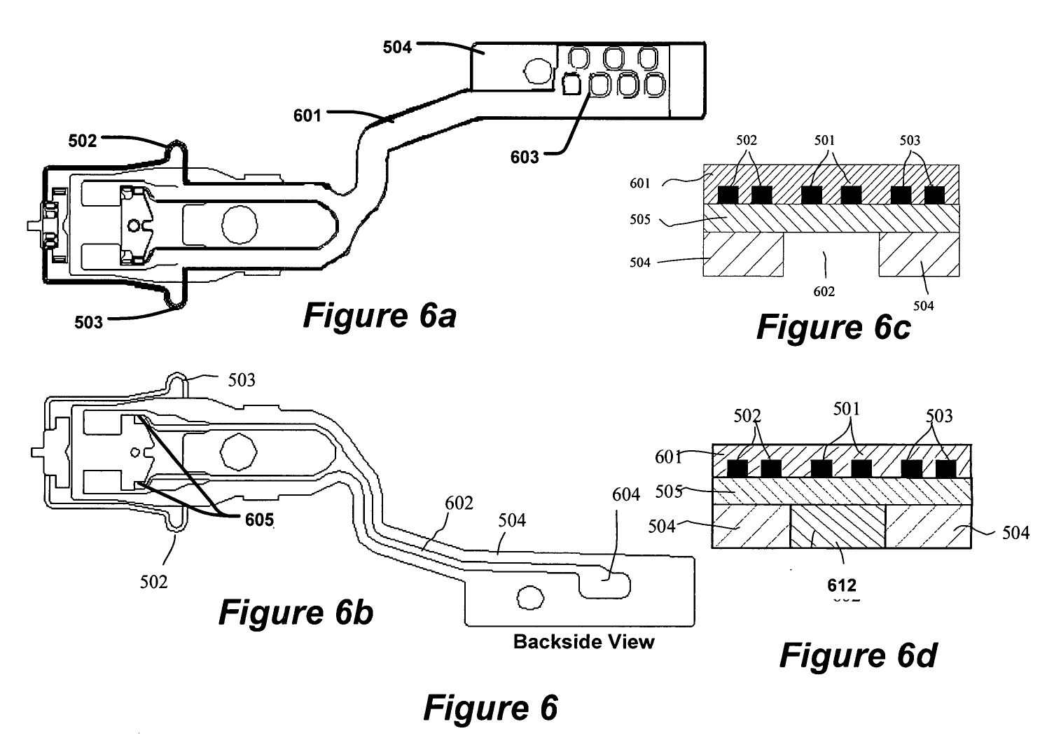

FIG. 6 illustrates a hard disk drive suspension flexure according to an embodiment of the present invention. As shown in FIG. 6c, in one embodiment an insulative coating (layer) 601 is applied to cover and separate the electrical traces 501,502,503 of the flexure. In this embodiment, the insulative layer 601 prevents electrical arcing between traces 501,502,503. In one embodiment, a portion 602 of the base layer (such as stainless steel) 504 opposite the micro-actuator traces 501 is etched away 602, such as by a chemical etching technique. As shown in the back side view of FIG. 6b, in one embodiment, the portion 602 opposite the micro-actuator traces 501 is etched away from one end 604 of the traces 501 (behind the micro-actuator connection pads 603; see FIG. 6a) to the other end of the traces 501 (behind the micro-actuator ball bonding pads 605 of the suspension tongue). In this embodiment, an insulative material 612 (such as epoxy, acrylic, polyimide, or other insulative film) is applied to fill the etched away portion 602. The insulative material (layer) 612 is applied by a method such as plating or spray coating.

In one embodiment, the portion 602 being etched out and filled with insulative material 612 reduces the overall stiffness of the suspension flexure (i.e., the insulative material is not as rigid as stainless steel). This improves flying height stability as well as loading and unloading characteristics. Further, in this embodiment, reducing the amount of stainless steel in the base 504 reduces the traces' electrical impedance and capacitance. Impedance and capacitance matching is important for optimizing the electrical performance (i.e., for preventing signal resonance at high data transmission frequencies and for preventing signal cross-talk).

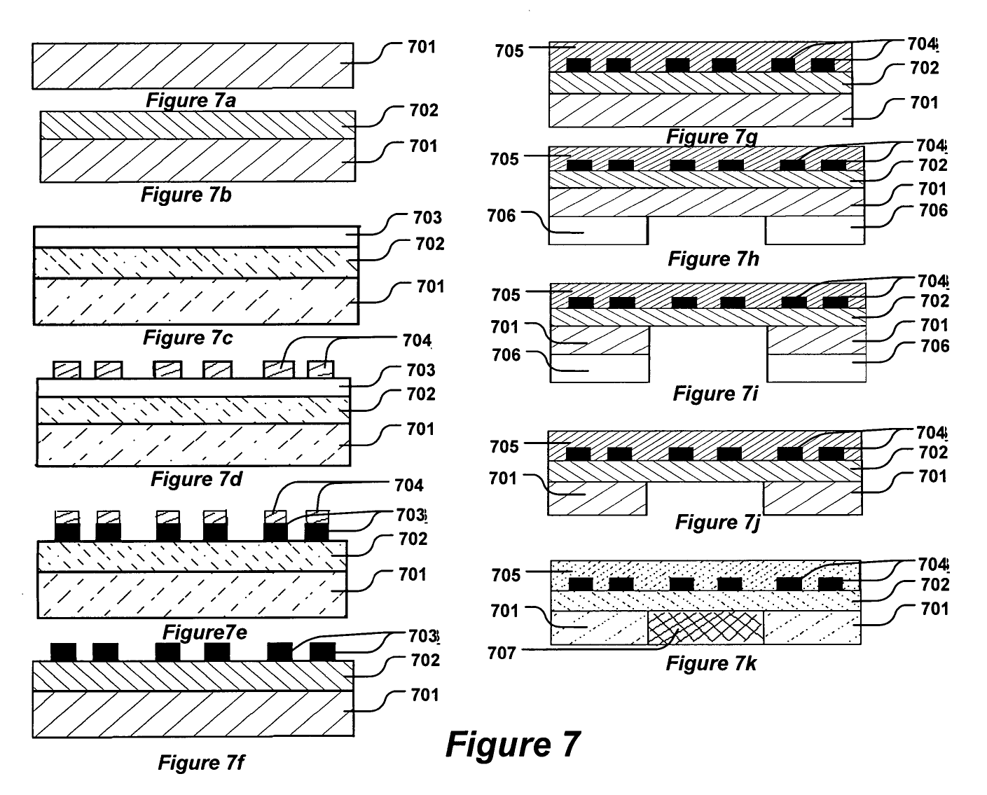

FIG. 7 illustrates a process of etching and laminating a suspension flexure according to an embodiment of the present invention. As shown in FIGS. 7a and 7b, in one embodiment, a base layer 701 is coated with a layer 702 such as a polyimide. As shown in FIG. 7c, in this embodiment, an electrically conductive layer (of, e.g., Copper, Gold, Nickel alloy, Platinum, or Tin) 703 is joined to the polyimide layer 702. As shown in FIG. 7d, in this embodiment, photo-resist elements 704 are joined to the conductive layer 703. As shown in FIG. 7e, in this embodiment, the electrically conductive layer 703 is etched away (such as by chemical etching) where no photo-resist 704 is present. As shown in FIGS. 7f and 7g, in this embodiment, an insulative coating 705 is applied to cover and fill the spaces between the traces 704.

As shown in FIG. 7h, in this embodiment, photo-resist elements 706 are joined to the base layer 701. As shown in FIG. 7i, in this embodiment, the base layer 701 is etched away (such as by chemical etching) where no photo-resist 704 is present. As shown in FIGS. 7j and 7k, in this embodiment, an insulative coating 707 is applied to fill the space between the portions of the base layer 701.

Although several embodiments are specifically illustrated and described herein, it will be appreciated that modifications and variations of the present invention are covered by the above teachings and within the purview of the appended claims without departing from the spirit and intended scope of the invention.

1-16. (canceled)

17. A method for manufacturing a hard disc drive suspension flexure comprising:
coupling a first electrical trace to a base element, said base element including an insulative layer and a conductive layer, and
sandwiching said insulative layer between said first electrical trace and said conductive layer, said conductive layer including a recess opposite the electrical trace.

18. The method of claim 17, wherein said first electrical trace is selected from the group consisting of copper, gold, nickel alloy, platinum, and tin.

19. The method of claim 17, wherein the insulative layer is polyimide.

20. The method of claim 17, wherein the conductive layer is stainless steel.

21. The method of claim 17, wherein said recess is created by an etching process.

22. The method of claim 21, wherein said etching process removes all of said conductive layer directly opposite of the first electrical trace.

23. The method of claim 17, wherein said recess is to be filled with a first insulation material.

24. The method of claim 23, wherein said first insulation material is selected from the group consisting of plastic, epoxy, and polyimide.

25. The method of claim 23, wherein said first insulation material is to be applied by a method selected from the group consisting of plating, printing, air spraying, and vacuum lamination.

26. The method of claim 23, wherein said first insulation material is opposite a read/write electrical trace and is 5 to 10 micro-meters(um) in thickness.

27. The method of claim 23, wherein said first insulation material is opposite a micro-actuator electrical trace and is 10 to 20 micro-meters(um) in thickness.

28. The method of claim 17, further comprising a second electrical trace adjacent said first electrical trace, wherein a layer of second insulation material is to be applied between said first electrical trace and said second electrical trace.

29. The method of claim 28, wherein said second insulation material is selected from the group consisting of plastic, epoxy, and polyimide.

30. The method of claim 28, wherein said second insulation material is to be applied by a method selected from the group consisting of plating, printing, air spraying, and vacuum lamination.

31. The method of claim 28, wherein said second insulation material is between a first and a second read/write electrical trace and is 10 to 15 micro-meters(um) in width.

32. The method of claim 28, wherein said second insulation material is between a first and a second micro-actuator electrical trace and is 15 to 25 micro-meters(um) in width.
